(19) United States
(12) Patent Application Publication
(10) Pub. No.: US 2026/0173492 A1
(43) Pub. Date: Jun. 18, 2026

(54) VANADIUM-DOPED HAFNIUM OXIDE FERROELECTRIC MATERIAL AND DEVICE, AND FABRICATION METHOD THEREOF

(71) Applicant: ECOLE POLYTECHNIQUE FEDERALE DE LAUSANNE (EPFL), Lausanne (CH)

(72) Inventors: Ehsan ANSARI, Ecublens (CH); Mihai Adrian IONESCU, Ecublens (CH); Igor STOLICHNOV, St-Sulpice (CH)

(21) Appl. No.: 19/420,140

(22) Filed: Dec. 15, 2025

Related U.S. Application Data
(60) Provisional application No. 63/735,088, filed on Dec. 17, 2024.

(51) Int. Cl. H10D 64/68; C23C 16/40; C23C 16/455; H10B 51/30; H10B 53/30; H10D 1/00; H10D 1/68; H10D 30/01; H10D 30/69; H10N 70/00; H10N 70/20

(52) U.S. Cl. CPC H10D 64/689; C23C 16/405; C23C 16/45553; H10B 51/30; H10B 53/30; H10D 1/041; H10D 1/68; H10D 30/0415; H10D 30/701; H10D 64/691; H10N 70/231; H10N 70/8836

(57) ABSTRACT

A ferroelectric device comprising at least one support and at least one ferroelectric layer provided on the at least one support. The ferroelectric layer comprises vanadium-doped Hafnium Oxide.

### CROSS-REFERENCE TO RELATED APPLICATIONS

This application is related to and claims priority on U.S. Provisional Application No. 63/735,088 filed Dec. 17, 2024, the disclosure of which is hereby incorporated herein by reference in its entirety for all purposes.

### FIELD OF THE INVENTION

The present invention relates to ferroelectric materials and devices, and CMOS-compatible ferroelectric thin-film insulators. The invention also relates to methods for fabrication of ferroelectric materials and devices.

### BACKGROUND

Research on CMOS-compatible ferroelectric thin films has intensified since the discovery of ferroelectricity in silicon-doped hafnium oxide (Si:HfO₂) by Böscke et al. Lead-free HfO₂-based ferroelectrics have been shown to be among the CMOS-compatible ferroelectrics with the highest remnant polarization (Pᵣ) and high scalability. Applications span from non-volatile (NV) memories (such as ferroelectric RAM and multi-level cell memory) to steep-slope and negative capacitance (NC) devices (e.g., ferroelectric FET and NC-FET), as well as programmable gates and neuromorphic devices. Several possible dopants have been introduced for HfO₂ ferroelectrics, including silicon (Si), zirconium (Zr), lanthanum (La), gadolinium (Gd), gallium (Ga), aluminium (Al), and yttrium (Y). Each of these dopants possesses specific characteristics; however, Si and Zr are generally regarded as the most promising due to their compatibility with CMOS technology.

However, despite all these currently proposed ferroelectric thin films in the state of the art, alternative and/or improved CMOS-compatible ferroelectrics and fabrication methods thereof are strongly desired.

### SUMMARY

According to one aspect of the present invention, a ferroelectric film, material and/or layer is provided. The ferroelectric film, material and/or layer comprises or consists of vanadium-doped Hafnium Oxide.

According to another aspect of the present invention, a ferroelectric device is provided. The ferroelectric device includes at least one ferroelectric film, material and/or layer comprising vanadium-doped Hafnium Oxide.

According to another aspect of the present invention, a ferroelectric device is provided. The ferroelectric device may comprise at least one support and at least one ferroelectric layer provided on the at least one support. The at least one ferroelectric layer comprises vanadium-doped Hafnium Oxide.

According to another aspect of the present invention, an electronic device is provided. The electronic device includes at least one ferroelectric film, material and/or layer comprising vanadium-doped Hafnium Oxide.

According to another aspect of the present invention, an electronic device is provided. The electronic device includes at least one ferroelectric device. The ferroelectric device may comprise at least one support and at least one ferroelectric layer provided on the at least one support. The at least one ferroelectric layer comprises vanadium-doped Hafnium Oxide.

According to another aspect of the present invention, a ferroelectric film, material and/or layer fabrication method or ferroelectric structure fabrication method is provided. The method comprises providing at least one support; and providing and/or depositing vanadium-doped Hafnium Oxide material by atomic layer deposition (ALD), and/or providing and/or depositing at least one vanadium-doped Hafnium Oxide layer and/or film by atomic layer deposition (ALD) on the at least one support.

This disclosure provides, for example, a CMOS-compatible ferroelectric thin-film insulator comprising or made of vanadium-doped hafnium oxide (V:HfO₂) which can be fabricated using an atomic layer deposition (ALD) process. Comparative electrical performance analysis of metal-ferroelectric-metal capacitors with varying V-doping concentrations, along with advanced material characterizations, confirm the ferroelectric behavior and reliability of V:HfO₂. With exemplary remnant polarization (Pᵣ) values up to 20 μC/cm², a coercive field (E_{c}) of 1.5 MV/cm, excellent endurance (>10¹¹ cycles without failure, extrapolated to 10¹² cycles), projected 10-year non-volatile retention (>100 days measured) and large measured exemplary grain sizes of about 180 nm, V:HfO₂ emerges as a promising robust candidate for, for example, non-volatile memory and neuromorphic applications. Importantly, negative capacitance (NC) effects were observed and analyzed in V:HfO₂ through pulsed measurements, demonstrating also its potential for NC applications. Finally, this novel ferroelectric further shows potential as a gating insulator, for example, for 3-terminal vanadium dioxide Mott-insulator devices and sensors, for example, achieved through an all-ALD process.

The above and other objects, features and advantages of the present invention and the manner of realizing them will become more apparent, and the invention itself will best be understood from a study of the following description with reference to the attached drawings showing some preferred embodiments of the invention.

### BRIEF DESCRIPTION OF THE SEVERAL VIEWS OF THE DRAWINGS

The accompanying drawings, which are incorporated herein and constitute part of this specification, illustrate the presently preferred embodiments of the invention, and together with the general description given above and the detailed description given below, serve to explain features of the invention.

FIG. 1A schematically shows an exemplary embodiment of a fabrication process flow of exemplary metal-ferroelectric-metal (MFM) capacitors and/or devices of the present disclosure as well as exemplary materials used for the fabricating the illustrated exemplary embodiment. FIG. 1B is a schematic of an exemplary optimized ALD process and cycle structure for 5.9% ferroelectric V:HfO₂. FIG. 1C is a TEM image and FIG. 1D is a high-resolution TEM image of a cross-section of an exemplary TiN/V:HfO₂/TIN MFM stack which was electrically woken up, the visible atomic fringes and large grains of >100 nm confirm the crystal quality. FIG. 1E is Top SEM image of the MFM structure after removal of the top TiN layer. Grain domains with a size of about 200 nm are visible. FIG. 1F shows an electron backscatter diffraction (EBSD) map of the same sample, showing an average grain size of about 180 nm. FIG. 1G is a TEM energy dispersive x-ray spectroscopy (EDX) mapping, and FIG. 1H is an elemental profile of the cross-section of the MFM capacitor. In the ferroelectric layer, an atomic concentration of 5.6% was measured for V. FIG. 1I is a grazing-incidence x-ray diffraction (GXRD) spectra of an annealed TiN/V:HfO₂/TiN MFM stack. The Inset represents low angle peaks with longer acquisition time and better precision.

FIG. 2 shows DC off-field piezoresponse force microscopy (PFM) mapping images of amplitude and phase of local piezoresponses within a same (1 μm²) area in FIGS. 2A and 2D for a negatively poled state, FIGS. 2B and 2E for a mixed state and FIGS. 2C and 2F for a positively poled state; pre-polarization was performed using DC biases of −5V, 2V, and 5V, respectively. The spatial uniformity of the phase and amplitude images over a one-hour scan time indicates robust retention of the ferroelectric. FIGS. 2D and 2H show DC off-field and DC on-field PFM loops of amplitude and phase of local piezoresponse measured at the marked arrow point in FIG. 2A. These experiments were carried out on an MFM capacitor with a thickness of 16 nm and 5.9% V-doping level.

FIG. 3 shows Pᵣ-E and current density-electric field loops for different VO₂ ALD cycle ratios (top row), measured using a 6 V, 10 kHz triangular stimulation; and shows εᵣ-E curves (bottom row) measured by a capacitance-voltage CV measurement method with a 100 kHz AC 30 mV RMS signal added to a DC voltage sweep of 6 V amplitude. All the MFM capacitors were annealed at 600° C. for two minutes. The highest remnant polarization of 17 μC/cm² and the highest εᵣ change was observed at optimum VO₂ ALD cycle ratio of 5.9%, considered the optimum fabrication condition.

FIG. 4A shows Pᵣ and εᵣ at room temperature (RT) as a function of VO₂ ALD cycle ratio. The error bar represents the standard deviation of five similar batches. FIG. 4B shows E_{c} verses VO₂ ALD cycle ratio, and FIG. 4C shows SS± and OS± retention test of 5.9% V:HfO₂ in MFM capacitor devices at 85° C. and at RT. FIG. 4D shows an endurance characteristic of an MFM capacitor with a 5.9% V:HfO₂ layer under 1 MHz, 4.8V (3 MV/cm), 5.2V (3.25 MV/cm), 5.6V (3.5 MV/cm) and 6V (3.75 MV/cm) pulse stimulation. An endurance of up to 10¹¹ cycles without failure was observed under a pulse stimulation of 4.8 V. Empty symbols represent breakdown. FIG. 4E shows Pᵣ-E hysteresis loops at different temperature conditions from 100 K to 350 K. FIG. 4F shows Pᵣ-E and FIG. 4G shows &-E curves at different annealing temperatures, ranging from 450° C. to 700° C. FIG. 4H shows 2Pᵣ as function of annealing and measurement temperatures, extracted from FIGS. 4E and 4F. FIG. 4I shows Pᵣ-E curves, and FIGS. 4J to 4L show εᵣ-E curves and frequency dispersion of, respectively, 8 nm, 16 nm, and 24 nm V:HfO₂ layers measured at RT.

FIG. 5A shows a benchmark study of endurance versus maximum 2Pᵣ during endurance test, comparing V:HfO₂ and recent reports on HfO₂-based ferroelectrics. Empty symbols represent breakdown. The data was obtained from references 14 to 21 for HZO, 22 to 23 for La:HZO, 24 for Si:HZO, 25 for Si:HfO₂, 9 for Ga:HfO₂, 8 for La:HfO₂, 26 for Gd:HfO₂, 10 for Al:HfO₂, 27 for Al:Si:HfO₂, and 28 for undoped HfO₂. FIG. 5B schematically shows an exemplary metal-ferroelectric-insulator-metal (MFIM) capacitor stack used for negative capacitance (NC) measurement as well as exemplary materials used for the fabricating the illustrated exemplary embodiment, FIG. 5C shows a circuit schematic of the NC measurement setup, FIG. 5D shows an input pulse voltage, (Vi), as a function of time, FIG. 5E shows MFIM capacitor current as a function of time and FIG. 5F shows charge as a function of time. FIG. 5G shows MFIM capacitor maximum stored charge (Qₘₐₓ), residual charge (Qᵣₑₛ) and the difference of them (Q_{d}) as a function of maximum voltage over the capacitor. FIG. 5H shows ferroelectric polarization versus electric field. The Experimental ‘S’-shaped characteristics (stars) well match the LGD theory. Also shown is a P-E_{f} curve of an MFM capacitor with 16 nm ferroelectric layer obtained by applying a 10 kHz 3.5V triangular pulse, and the dashed line is the slope of the linear NC region.

FIG. 6 shows an exemplary metal-ferroelectric-metal (MFM) structure or device of the present disclosure, and elemental mapping images. A Pᵣ-E hysteresis loop and 2Pᵣ versus endurance are also shown demonstrating remnant polarization Pᵣ values up to 20 μC/cm², a coercive field E_{c} of 1.5 MV/cm, and excellent endurance (>10¹¹ cycles without failure, extrapolated to 10¹² cycles).

FIGS. 7A to 7D schematically show exemplary devices including the vanadium-doped Hafnium Oxide film, material and/or layer of the present disclosure. FIG. 7E schematically shows exemplary steps of a fabrication method of a ferroelectric material and/or layer, or a ferroelectric structure and/or device.

Herein, identical reference numerals are used, where possible, to designate identical elements that are common to the figures. Also, the images are simplified for illustration purposes and may not be depicted to scale.

### DETAILED DESCRITION OF THE SEVERAL EMBODIMENTS

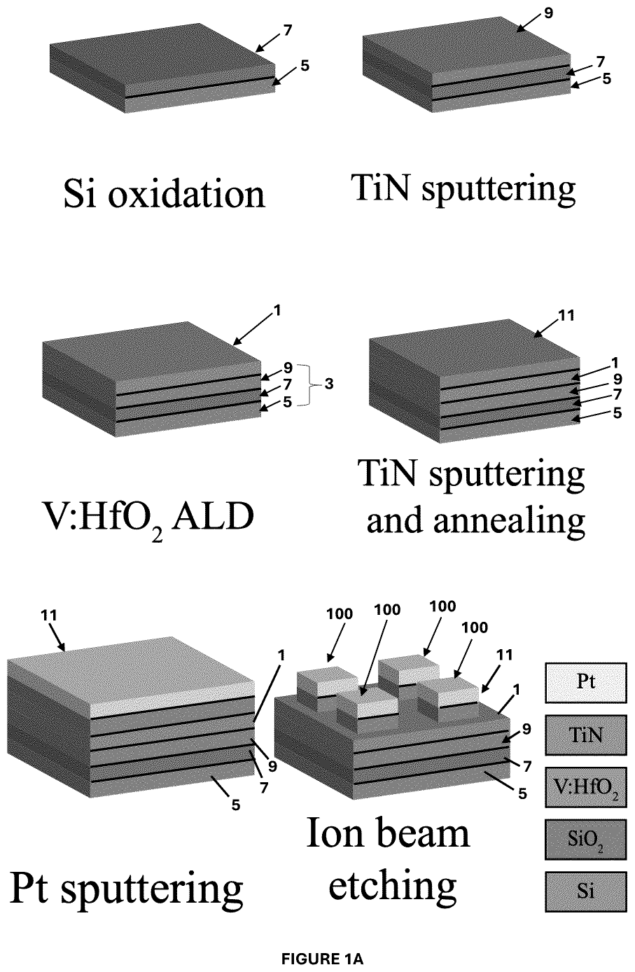

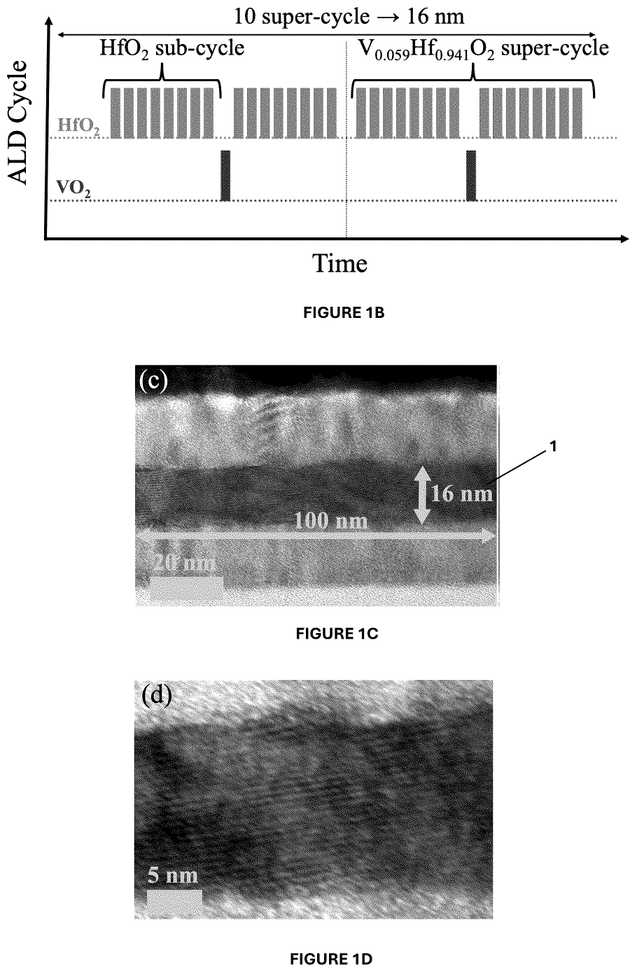

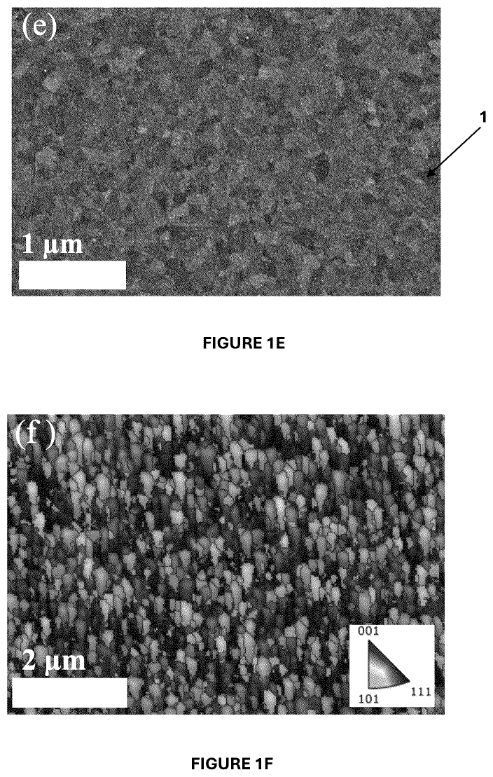

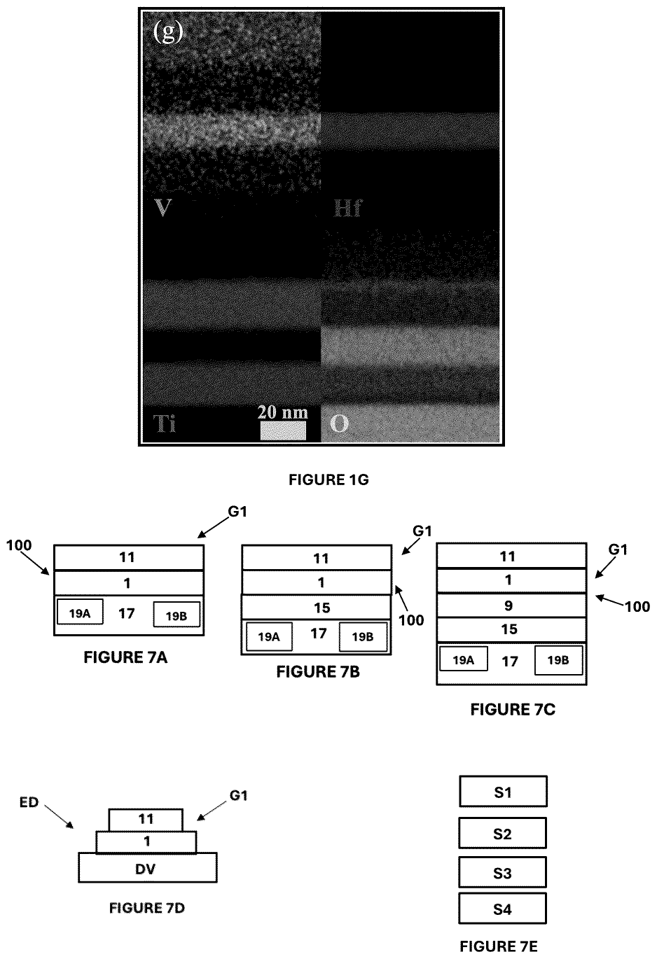

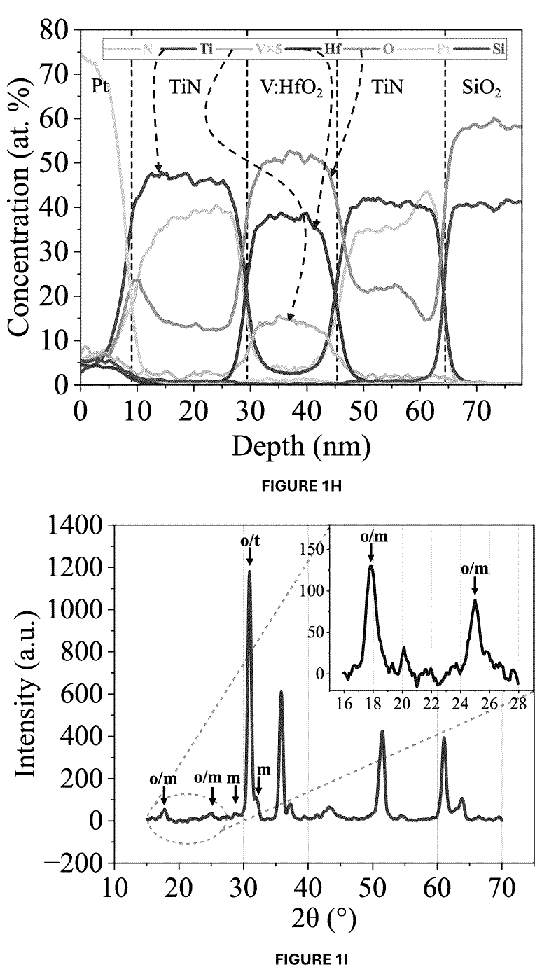

According to one embodiment, a ferroelectric film, material and/or layer 1 is provided. The ferroelectric film, material and/or layer 1 comprises or consists of vanadium-doped Hafnium Oxide V:HfO₂. The vanadium-doped Hafnium Oxide V:HfO₂ film, material and/or layer 1 may be provided on at least one support 3. The support 3 may comprise at least one layer and/or at least one substrate. FIG. 1A schematically shows the vanadium-doped Hafnium Oxide V:HfO₂ film, material and/or layer 1 provided and/or deposited on a plurality of supports comprising a supporting substrate 5, and supporting layers 7, 9.

The vanadium-doping level is, for example, between 3% and 11%, or preferably between 3% and 7.5%, or more preferably between 5% and 7.5%, or more preferably between 5.5% and 7.25%, or even more preferably between 5.5% and 7%. That is, the vanadium-doping concentration is between 3 at. % and 11 at. %, or more preferably between 5% at. % and 7.5% at. %, or more preferably between 5.5% at. % and 7.25% at. %, or even more preferably between 5.5% at. % and 7% at. %. Atomic percent at. % specifies the fraction of the host that has been replaced by the dopant vanadium. Atomic percent at. % can, for example, be measured by energy dispersive x-ray spectroscopy (EDX).

The vanadium-doping concentration is, for example, between about 3 at. % and about 11 at. %, or more preferably between about 5% at. % and about 7.5% at. %, or more preferably between about 5.5% at. % and about 7.25% at. %, or even more preferably between about 5.5% at. % and about 7% at. %

In an exemplary embodiment, the vanadium-doped Hafnium Oxide film, material and/or layer 1 may, for example, have a grain size or average grain size >10 nm or >100 nm. The vanadium-doped Hafnium Oxide film, material and/or layer 1 may have a grain size or average grain size >10 nm and <1000 nm, or >10 nm and <200 nm, or more preferably >150 nm and <300 nm, or >150 nm and <200 nm, as further detailed below. In an exemplary embodiment, the vanadium-doped Hafnium Oxide film, material and/or layer 1 has, for example, an average grain size of about 180 nm, or 180 nm±5%.

In an exemplary embodiment, the vanadium-doped Hafnium Oxide film, material and/or layer 1 may have a thickness t>1 nm or preferably >15 nm. The thickness t may, for example, be between 5 nm and 50 nm, or between 5 nm and 35 nm, or between 5 nm and 25 nm, or between 5 nm and 24 nm, or between 5 nm and 20 nm, as further detailed below in relation to the provided ferroelectric properties.

The thickness t may, for example, be between 7 nm and 50 nm, or between 7 nm and 35 nm, or between 7 nm and 25 nm, or between 7 nm and 24 nm, or between 7 nm and 20 nm. The thickness t may, for example, be between 8 nm and 50 nm, or between 8 nm and 35 nm, or between 8 nm and 25 nm, or between 8 nm and 24 nm, or between 8 nm and 20 nm.

The thickness t may, for example, be measured in the deposition direction and/or stacking direction of the vanadium-doped Hafnium Oxide film, material and/or layer 1.

The vanadium-doped Hafnium Oxide film, material and/or layer 1 is or forms an insulator film, material and/or layer 1. The vanadium-doped Hafnium Oxide film, material and/or layer 1 advantageously is a CMOS-compatible ferroelectric thin-film insulator.

In an exemplary embodiment, the vanadium-doped Hafnium Oxide film, material and/or layer 1 is, for example, configured to provide a remnant polarization Pᵣ values up to 20 μC/cm².

Alternatively or additionally, the vanadium-doped Hafnium Oxide film, material and/or layer 1 may, for example, be configured to provide a coercive electric field E_{c} of about 1.5 MV/cm; and/or configured to provide an Endurance exceeding 10¹¹ switching cycles without failure; and/or configured to provide a projected non-volatile retention for over 10 years.

In an exemplary embodiment, a ferroelectric device 100 is provided and the ferroelectric device 100 includes at least one ferroelectric film, material and/or layer 1 comprising the vanadium-doped Hafnium Oxide. The ferroelectric device 100 may comprise the at least one support 3 and at least one ferroelectric film, material and/or layer 1 provided and/or deposited on the at least one support 3. As mentioned, the support 3 may, for example, comprise at least one layer and/or at least one substrate such as the supporting substrate 5, and/or the supporting layers 7, 9.

The ferroelectric device 100 may, for example, include at least one electrode 9, and the ferroelectric film, material and/or layer 1 is provided on and/or in electrical contact and operatively connected with the at least one electrode 9. This permits an electrical potential difference and/or voltage to be applied to the ferroelectric film, material and/or layer 1 and the vanadium-doped Hafnium Oxide, for example using a voltage source.

In an exemplary embodiment, the ferroelectric device 100 may include at least a first electrode 9 and at least a second electrode 11. The ferroelectric film, material and/or layer 1 is provided in electrical contact and operatively connected with the first and second electrodes 9, 11 for applying an electrical potential difference and/or voltage to the first and second electrodes 9, 11 and to and/or across the at least one ferroelectric film, material and/or layer 1, for example, using a voltage source.

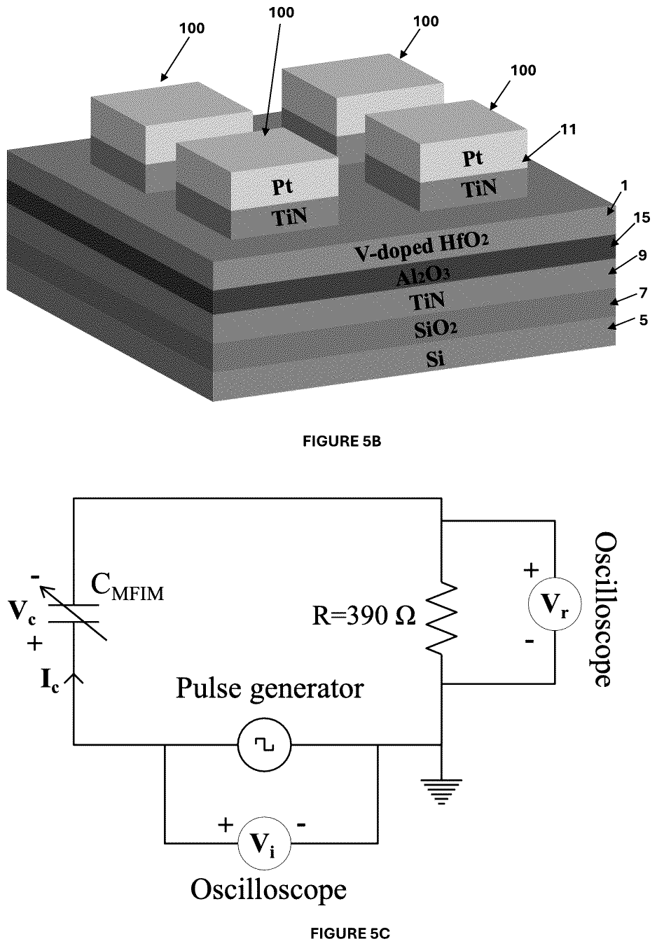

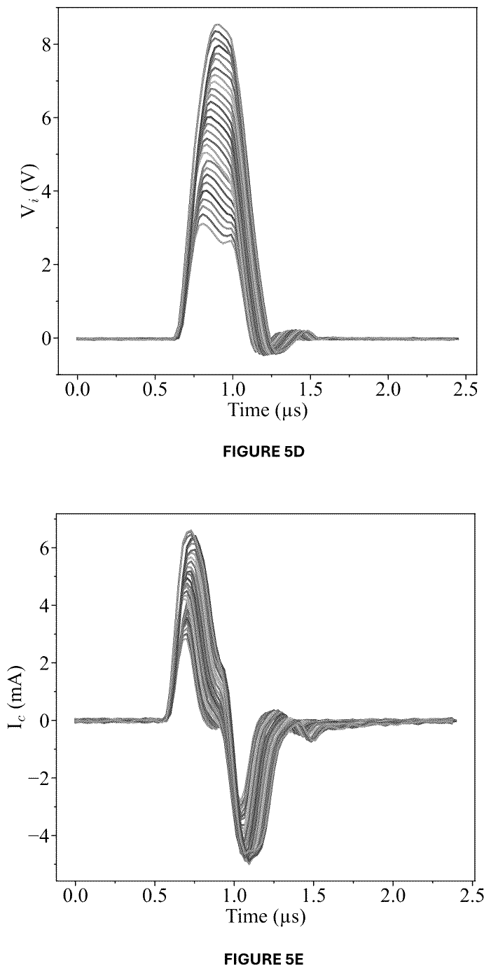

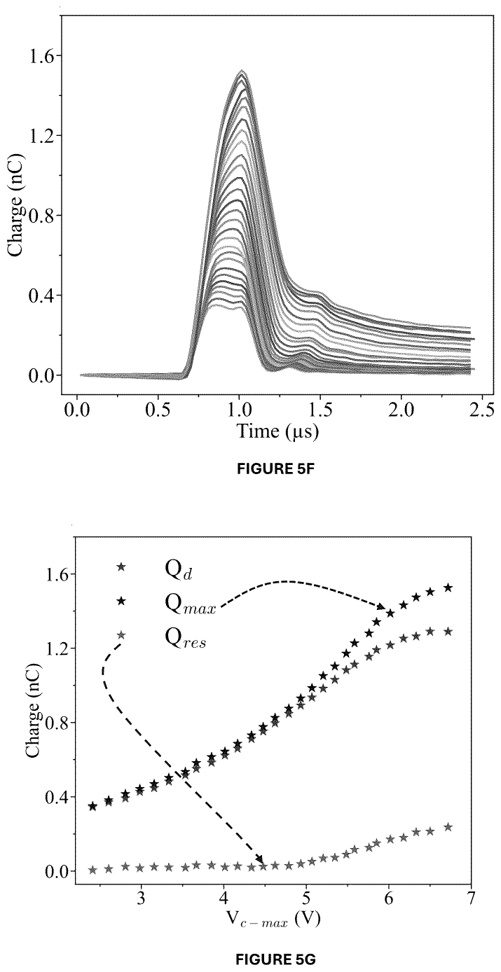

The electrode 9, 11 comprises, for example, at least one material or layer and/or at least one conductive. The electrode 9, 11 may comprise, for example, at least one conductive material or layer. The electrode 9, 11 may comprise, for example, at least one metal, or at least one metal silicide. The electrode 9, 11 may comprise, for example, at least one metal oxide or at least one metal nitride. The electrode 9, 11 may comprise, for example at least one of TiN, TiSiNₓ, TaNₓ, TaSiNₓ, NbN, WNₓ, MON; W, Pt, Ru, Mo, Ir, nickel, aluminium, MoO₂, IrO₂, and RuOₓ. The thickness of the at least one material or layer of the electrode may, for example, be between 10 nm and 100 nm. In the illustrated exemplary embodiment of FIGS. 1A and 5B, the first electrode 9 comprises TiN, and the second electrode 11 comprises TiN and platinum Pt.

In an exemplary embodiment, the ferroelectric film, material and/or layer 1 is an atomic layer deposition ALD or a plasma assisted atomic layer deposition ALD deposited ferroelectric film, material and/or layer. The electrodes may, for example, be deposited by sputtering deposition.

In an exemplary embodiment, the ferroelectric device 100 is and/or forms a ferroelectric capacitor device.

In an exemplary embodiment, the ferroelectric device 100 may, for example, form and/or include a metal-ferroelectric-metal MFM device (see, for example, FIG. 1A). The vanadium-doped Hafnium Oxide film, material and/or layer 1 is, for example, provided or deposited on the first or back electrode 9, and the second or top electrode 11 provided or deposited on the vanadium-doped Hafnium Oxide film, material and/or layer 1.

In an exemplary embodiment, the ferroelectric device 100 may form and/or include a metal-ferroelectric-insulator-metal MFIM device including at least one insulator material and/or layer 15 located between the first electrode 9 and the ferroelectric film, material and/or layer 1; and/or located between the second electrode 11 and the ferroelectric film, material and/or layer 1 (see, for example, FIG. 5B).

The vanadium-doped Hafnium Oxide film, material and/or layer is, for example, provided on the first or back electrode 9, the insulator material or layer 15 is for example provided on the vanadium-doped Hafnium Oxide film, material and/or layer 1 and the first or back electrode 9, and the second or top electrode 11 is for example provided on the vanadium-doped Hafnium Oxide film, material and/or layer 1. The insulator material or layer 15 is, for example, provided on the first or back electrode 9 between the vanadium-doped Hafnium Oxide film, material and/or layer 1 and the first or back electrode 9.

The at least one insulator material and/or layer 15 may, for example, have a thickness between 1 nm and 10 nm, or between 2 nm and 5 nm. The at least one insulator material and/or layer 15 may, for example, be deposited using ALD. The at least one insulator material and/or layer 15 may be any type of metal oxides, for example, be Al₂O₃, HfO₂, SiO₂, ZrO₂, Si₃N₄, TiO₂, La₂O₃, or Ta₂O₃. In an exemplary embodiment, the insulator material and/or layer 15 includes Al₂O₃. For example, 3 nm of Al₂O₃ as a linear dielectric deposited with ALD before the V:HfO₂ layer.

In an exemplary embodiment, the ferroelectric device 100 may, for example, form and/or include a metal-ferroelectric-semiconductor device MFS including at least one semiconductor material or layer 17. The ferroelectric film, material and/or layer 1 is, for example, provided in electrical contact and operatively connected with at least one electrode 9, 11 and in electrical contact and operatively connected with the at least one semiconductor material or layer 17. The ferroelectric film, material and/or layer 1 is, for example, provided or deposited on the at least one semiconductor material or layer 17 (see, for example. FIGS. 7A to 7C). The at least one semiconductor material or layer 17 may, for example, comprise silicon.

In an exemplary embodiment, first and second terminals or electrodes 19A, 19B (for example, drain and source terminals) may, for example, be included and configured to receive a voltage or potential difference for generating current flow in the at least one semiconductor material or layer 17. A device gate G1 may, for example, include the ferroelectric film, material and/or layer 1 and for example electrode 11 for, for example, controlling the current passing in and/or through the semiconductor material or layer 17 (see, for example, FIG. 7A).

The gate or device gate G1 may be a gate of an electronic device ED that is a field effect device, for example, a field effect transistor, schematically and generally represented in FIG. 7D, the element DV representing device elements(s) of the electronic device ED to which the gate G1 is operatively connected.

In some exemplary embodiments, at least one insulator 15 and/or layer comprising at least one insulator material 15 may be included located between the semiconductor material or layer 17 and the ferroelectric film, material and/or layer 1 (see, for example, FIGS. 7B and 7C). The ferroelectric film, material and/or layer 1 may be included between first and second electrodes 9, 11 which are included in the device gate G1 (see for example, FIG. 7C).

In an exemplary embodiment, the electronic device ED includes the ferroelectric device 100 and includes at least one device gate G1 that includes the ferroelectric device 100.

The electronic device ED including at least one device gate G1 may be or comprise, for example, at least one of a VO₂ phase-change switch, a VO₂ phase-change sensor, and a ferroelectric field-effect transistor.

In an embodiment, the electronic device ED comprises at least one Mott-Insulator device and/or at least one three-terminal Mott-Insulator device, wherein the vanadium-doped Hafnium Oxide film, material and/or layer 1 and at least one device gate G1 are included and are configured as a gating insulator for the three-terminal Mott-insulator device. The Mott-insulator device may, for example, include a configuration such as that previously described in relation to FIGS. 7A and 7D) that includes, for example, first and second terminals or electrodes 19A, 19B (for example, drain and source terminals).

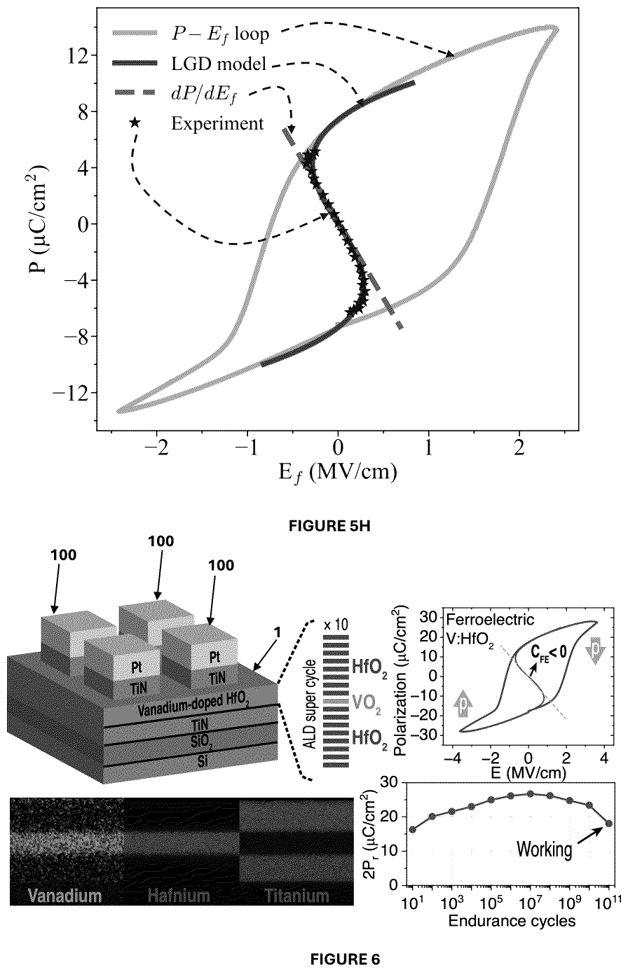

As mentioned, the ferroelectric device 100 is and/or forms a ferroelectric capacitor device. In an exemplary embodiment, the electronic device ED includes at least one ferroelectric capacitor device. The ferroelectric capacitor device is, for example, configured to be set to at least a first and second polarization states (for example, p+ and p−) when an (external) electric field is applied to the ferroelectric device 100 and/or the vanadium-doped Hafnium Oxide film, material and/or layer 1 (see, for example, FIG. 6); and is configured to switch between the first and second first and second polarization states when an (external) electric field is applied to the ferroelectric device 100 and/or the vanadium-doped Hafnium Oxide film, material and/or layer 1. These polarization states permit to store information (such as binary data) based on the states and/or the polarization orientation/state. The electronic device ED may be or may comprise at least one of: a non-volatile memory, a ferroelectric random-access memory, and a multi-level cell memory.

As mentioned, the ferroelectric device 100 may be or may form a ferroelectric capacitor device, and the electronic device ED includes at least one ferroelectric capacitor device comprising, for example, at least one electrode, or at least first and second electrodes in electrical contact and operatively connected to the vanadium-doped Hafnium Oxide film, material and/or layer 1. The ferroelectric capacitor device may be a negative capacitance capacitor or configured to provide a negative capacitance or negative capacitance effect. For example, stored charge changes in the opposite direction to changes in the applied voltage, for example, increasing when the voltage decreases.

The negative capacitance capacitor may for example be included in the gate G1 previously described and in FET devices described previously. The electronic device ED may comprise a negative capacitance field-effect transistor and/or a steep-slope and negative capacitance field-effect transistor.

The electronic device ED may alternatively comprise at least one of: a ferroelectric tunnel junction comprising the vanadium-doped Hafnium Oxide film, material and/or layer 1 having thickness permitting charge carriers (electrons) to pass/tunnel therethrough, the vanadium-doped Hafnium Oxide film, material and/or layer 1 being located between first and second electrodes which an operating voltage is applied, a programmable logic gate, a neuromorphic computing device, an artificial synapses and a spiking or artificial neuron.

Capacitors, Ferroelectric FETs (FeFETs), Ferroelectric RAM (FeRAM), memory devices and/or multi-level cell memory may comprise or be formed by the metal-ferroelectric-metal (MFM) and/or metal-ferroelectric-insulator-metal (MFIM) structures described herein.

As mentioned, in an exemplary embodiment, the ferroelectric film, material and/or layer 1 is an atomic layer deposition ALD or a plasma assisted atomic layer deposition ALD deposited ferroelectric film, material and/or layer. The electrodes may, for example, be deposited by sputtering deposition.

In an exemplary embodiment, another aspect of the present disclosure concerns a ferroelectric structure and/or device fabrication method; or a ferroelectric film, material or layer fabrication method.

The method is, for example, a CMOS-compatible fabrication method.

The method includes comprising providing at least one support 3, for example, at least one supporting layer 7, 9 and/or at least one supporting substrate 5 (S1); and providing and/or depositing vanadium-doped Hafnium Oxide layer or at least one vanadium-doped Hafnium Oxide layer or film by atomic layer deposition on the at least one support 3 (S2). Vanadium-doped ferroelectric/high-k dielectric material is provided or deposited by atomic layer deposition ALD on at least one support layer or substrate.

The vanadium-doped Hafnium Oxide material and/or layer is, for example, deposited by atomic layer deposition ALD using tetrakis(ethylmethylamid)hafnium(IV) (TEMAH) and water (H₂O) are used as HfO₂ precursors.

In an embodiment, tetrakis(ethylmethylamino)vanadium (TEMAV) and ozone (O₃) may be used as VO₂ precursors. In another exemplary embodiment, tetrakis(ethylmethylamino)vanadium (TEMAV) and oxygen (O₂) are used as VO₂ precursors.

VO₂ doping cycles are distributed between HfO₂ cycles during deposition of the vanadium-doped Hafnium Oxide layer to assure vanadium doping and a desired vanadium doping concentration. VO₂ doping cycles are distributed between HfO₂ cycles for example distributed homogeneously between HfO₂ cycles during deposition of the vanadium-doped Hafnium Oxide layer. Alternatively, VO₂ doping cycles may be distributed non-homogenously or in a super lattice or layered structure between HfO₂ cycles during deposition of the vanadium-doped Hafnium Oxide layer. In one exemplary embodiment, the Hf:V ratio is 16:1.

A Hf:V cycle ratio is used to provide a vanadium-doping concentration level that is, for example, between 3% and 11%, or preferably between 3% and 7.5%, or more preferably between 5% and 7.5%, or more preferably between 5.5% and 7.25%, or even more preferably between 5.5% and 7%. That is, the vanadium-doping concentration is between 3 at. % and 11 at. %, or more preferably between 5% at. % and 7.5% at. %, or more preferably between 5.5% at. % and 7.25% at. %, or even more preferably between 5.5% at. % and 7% at. %. Atomic percent at. % specifies the fraction of the host that has been replaced by the dopant vanadium.

The vanadium-doping concentration is, for example, between about 3 at. % and about 11 at. %, or more preferably between about 5% at. % and about 7.5% at. %, or more preferably between about 5.5% at. % and about 7.25% at. %, or even more preferably between about 5.5% at. % and about 7% at. %

In an exemplary embodiment, the thickness of the deposited and/or provided vanadium-doped Hafnium Oxide film, material and/or layer 1 may have a thickness t>1 nm or >5 nm or preferably >15 nm. The thickness t may, for example, be between (i) 1 nm or 5 nm and (ii) 50 nm, or between (i) 1 nm or 5 nm and (ii) 35 nm, or between (i) 1 nm or 5 nm and (ii) 25 nm, or between (i) 1 nm or 5 nm and (ii) 24 nm, or between (i) 1 nm or 5 nm and (ii) 20 nm, as further detailed below in relation to the provided ferroelectric properties.

The thickness t may, for example, be between 7 nm and 50 nm, or between 7 nm and 35 nm, or between 7 nm and 25 nm, or between 7 nm and 24 nm, or between 7 nm and 20 nm. The thickness t may, for example, be between 8 nm and 50 nm, or between 8 nm and 35 nm, or between 8 nm and 25 nm, or between 8 nm and 24 nm, or between 8 nm and 20 nm.

In an exemplary embodiment, the provided and/or deposited vanadium-doped Hafnium Oxide film, material and/or layer 1 may, for example, have a grain size or average grain size >10 nm. The vanadium-doped Hafnium Oxide film, material and/or layer 1 may have a grain size or average grain size >10 nm and <1000 nm, or >100 nm and <200 nm, or more preferably >150 nm and <300 nm, or >150 nm and <200 nm, as further detailed below. In an exemplary embodiment, the vanadium-doped Hafnium Oxide film, material and/or layer 1 has, for example, an average grain size of about 180 nm, or 180 nm±5%.

The method may include, for example, providing and/or depositing (S3) at least one electrode 9, 11 on the at least one support 3 for operatively electrically contacting the vanadium-doped Hafnium Oxide material and/or layer 1 for applying an electrical potential difference or voltage to the vanadium-doped Hafnium Oxide material and/or layer 1. The electrode may, for example, be provided and/or deposited on the vanadium-doped Hafnium Oxide material and/or layer 1. A first (or back) electrode 9 may, for example, be provided and/or deposited (directly or indirectly) on the support 3 and the vanadium-doped Hafnium Oxide material and/or layer 1 provided and/or deposited (directly or indirectly) on the first electrode 9. A second (or top) electrode 11 may, for example, be provided and/or deposited on (directly or indirectly) the vanadium-doped Hafnium Oxide material and/or layer 1. The electrodes may comprise the materials and structures previously described herein. The electrodes may have the thicknesses previously described herein. The electrodes may, for example, be deposited by sputtering deposition.

The method may also include carrying out annealing and/or rapid thermal annealing (S4). In an exemplary embodiment, annealing and/or rapid thermal annealing may be carried out in a nitrogen (N₂) atmosphere at a temperature >300° C. for a duration between 1 to 20 minutes.

In an embodiment, the method may include providing and/or depositing the above mentioned at least one insulator material or layer 15 on the first (or back) electrode 9 prior to the provision and/or deposition of the at least one vanadium-doped Hafnium Oxide layer or film 1.

The method may, for example, be used to provide and/or produce at least one MFM or MFIM device described previously, or the Mott-insulator device in which the vanadium-doped Hafnium Oxide layer or film 1 forms a gating insulator of the gate of the Mott-insulator device.

As described and demonstrated below in detail, disclosed herein is a CMOS-compatible ferroelectric thin-film insulator composed of vanadium-doped hafnium oxide (V:HfO₂), which can be fabricated via atomic layer deposition (ALD). The material is successfully integrated into both exemplary metal-ferroelectric-metal (MFM) and metal-ferroelectric-insulator-metal (MFIM) structures, achieving exemplary remnant polarization (Pᵣ) values up to 20 μC/cm², a coercive field (E_{c}) of 1.5 MV/cm, and demonstrating high endurance (>10¹¹ cycles without degradation, extrapolated to 10¹² cycles). Furthermore, the material exhibits excellent non-volatile retention, with a projected lifespan exceeding 10 years, and features large grain sizes (about 100 to 200 nm).

The disclosed V:HfO₂ thin film addresses the stringent performance requirements of next-generation electronic devices, including non-volatile memory, steep-slope transistors, and neuromorphic computing components.

This invention relates, for example, to ferroelectric materials for advanced semiconductor applications, particularly a vanadium-doped hafnium oxide (V:HfO₂) thin-film insulator that can be fabricated using a CMOS-compatible atomic layer deposition (ALD) process.

Traditional ferroelectric materials often face challenges in compatibility with CMOS processes and scalability for emerging electronic devices. The disclosed V:HfO₂ material addresses these issues, offering superior remnant polarization, coercive field characteristics, and endurance, making it suitable for a wide range of non-volatile memory and logic applications, as well as neuromorphic computing architectures.

Vanadium doping of hafnium oxide provides ferroelectric properties by stabilizing the orthorhombic phase, critical for achieving robust polarization. The ALD process ensures conformal deposition over complex geometries, supporting integration into advanced device architectures. The material's large grain size (about 100 to 200 nm) contributes to improved device performance and reliability. The method is versatile, allowing the introduction of additional dopants or adaptation to other high-k dielectric materials, such as hafnium zirconium oxide (HZO), to further optimize electronic properties.

Concerning advantages and Industrial Applications, the V:HfO₂ thin film demonstrates potential in various next-generation applications, including:
Non-Volatile Memories (NVM): FeRAM, FeFET, FTJ, and multi-level cell designs.
Steep-Slope and Negative Capacitance Devices: Enabling energy-efficient transistors.
In-memory and Neuromorphic Computing: Artificial synapses and neurons for brain-inspired architectures.
Sensors and Advanced Logic Gates: Utilizing ferroelectric gating for novel computational elements.

The disclosed technology can also facilitate the development of Mott-insulator-based devices, enabling new paradigms in sensing and computation.

This invention presents a novel ferroelectric material and process for integration into CMOS-compatible devices, offering a pathway to enhanced performance and broader applications in future electronic systems.

The vanadium-doped HfO₂ technology is at TRL 5-6, reflecting validation in relevant environments and successful prototyping for memory and logic applications. Readiness validated for FeRAM, FeFETs, and multi-level cell memory using metal-ferroelectric-metal (MFM) and metal-ferroelectric-insulator-metal (MFIM) structures. MFM and MFIM capacitors were successfully fabricated and demonstrated robust ferroelectric performance with a measured endurance exceeding 10¹¹ cycles without failure and extrapolated to 10¹² cycles and non-volatile retention projected to 10 years, with >100 days tested under laboratory conditions. These devices are key structures for memory applications, and their performance was comparable or superior to state-of-the-art doped high-k dielectrics.

Vanadium-doped HfO₂ (or H₂O) is fully compatible with CMOS technology due to a low thermal budget and processing via atomic layer deposition (ALD), a widely utilized technique in modern semiconductor industry. The feasibility of integration with advanced semiconductor nodes is already proven, as exemplified by its compatibility with high-k metal-gate (HKMG) technology used in fabricating silicon-doped HfO₂ FeFET memories.

In summary, vanadium-doped HfO₂ is a cutting-edge ferroelectric material offering high endurance, excellent retention, and scalability for CMOS-compatible memory and logic devices. Prototyping and testing in relevant environments have been successfully demonstrated for multiple device structures (MFM, MFIM), demonstrating the material's readiness for advanced applications and its technology level of TRL 5. While further optimization and large-scale manufacturing validation are needed to reach TRL 7-8, the technology is robust and ready for pilot-scale development and extended operational testing.

Technical Advantages include:
1. High remnant polarization (Pᵣ) of ˜20 μC/cm², comparable to state-of-the-art doped high-k dielectrics.
2. Excellent endurance (>10¹¹ cycles measured, extrapolated to 10¹² cycles) ensures long-lasting performance in memory applications.
3. Projected 10-year non-volatile (NV) retention, validated by extended testing (>100 days measured).
4. Larger Grain Size and Improved Crystallinity: Grain sizes of about 100 to 200 nm, significantly larger than those of conventional doped HfO₂ materials, confirmed by advanced characterizations (TEM, SEM, EBSD, PFM).
5. CMOS Compatibility: Fully compatible with existing CMOS processes, leveraging atomic layer deposition (ALD) and a low thermal budget.
6. Multi-Functionality: Compatible with non-volatile memories (FeRAM, FeFET), steep-slope devices (NCFET), and neuromorphic applications enabling a wide range of applications. In addition, a unified all-ALD process using a single vanadium precursor enables seamless integration with other materials, including VO₂ for Mott insulator devices.

Commercial Advantages include:
1. Scalability for mass Production
2. Broad market applications: Applications span multiple high-value sectors, including non-volatile memories (FeRAM, FeFET), steep-slope logic devices, negative capacitance devices (NCFET), neuromorphic computing systems, and VO₂-based Mott insulators for next-generation computational architectures.
3. Competitive performance: Endurance and retention characteristics are on par with or surpass current industry benchmarks, making V:HfO₂ a strong candidate for next-generation memory technologies. Large grain size and robust piezoelectric response provide unique selling points over other ferroelectric materials.
4. Reduced time-to-market: Compatibility with established semiconductor processes and materials enables quicker adoption and integration into existing manufacturing pipelines.

Commercial applications include:

### 1. Non-Volatile Memories (NVMs):

Vanadium-doped hafnium oxide (V:HfO₂) is an excellent candidate for ferroelectric random-access memory (FeRAM), ferroelectric field-effect transistors (FeFETs) and ferroelectric tunnel junctions (FTJs). High endurance and retention properties make it r robust candidate for industrial, automotive, and IoT applications where low power and high reliability are critical.

V:HfO₂ are also suitable for low-power, high-density storage solutions in mobile and edge devices. V:HfO₂ FeFET can also support multi-level cell (MLC) memory for higher data storage per unit area.

### 2. Steep-Slope and Negative Capacitance Devices:

V:HfO₂ demonstrated negative capacitance behaviour enables energy-efficient transistors negative capacitance field-effect transistors (NCFETs) for low-power logic circuits, crucial for extending Moore's Law and integration into low-power processors for applications in smartphones, wearables, and battery-operated devices.

### 3. In-Memory and Neuromorphic Computing:

The proposed ferroelectric enables in-memory computing devices on advanced CMOS platforms and offers a practical perspective to implement neuromorphic meristive devices. The large grain size, high endurance, and robust polarization switching characteristics of V:HfO₂ make it ideal for artificial synapses in neuromorphic devices that emulate brain-like computational architectures.

### 4. Piezoelectric Applications:

Significant piezoelectric response of V:HfO₂ enables its use in MEMS sensors, actuators, RF filters an transducers (e.g., in automotive, aerospace, and medical applications).

### 5. Programmable Logic Gates:

V:HfO₂ based devices can be used for programmable gates in reconfigurable computing, aiding the development of flexible and adaptive electronic circuits.

### 6. Thin-Film Transistors for Advanced Displays:

Integration of V:HfO₂ into display backplanes for OLED and micro-LED technologies could improve power efficiency and switching speeds.

### 7. Mott Insulator-Based Devices:

The compatibility of V:HfO₂ with VO₂ fabrication processes opens avenues for future 3-terminal Mott devices used in ultra-fast switches, neuromorphic systems, and unconventional computing architectures.

### 8. Emerging Semiconductor Applications:

High-quality ferroelectric properties and compatibility with advanced technology nodes (e.g., 28 nm HKMG and below) make V:HfO₂ a future-proof material for use in advanced CMOS and beyond-CMOS technologies.

In summary, V-doped HfO₂'s versatility supports a broad range of applications in memory, logic, neuromorphic, and piezoelectric domains, addressing current and emerging semiconductor industry needs.

The present disclosure concerns (I) a CMOS-Compatible Ferroelectric Thin Film, that is, for example, a ferroelectric thin-film insulator comprising vanadium-doped hafnium oxide (V:HfO₂). The film can for example be deposited using an atomic layer deposition (ALD) process.

The present disclosure concerns (II) Integrated Device Structures, where the thin film is, for example, incorporated into at least one of the following device configurations: Metal-ferroelectric-metal (MFM) capacitors; and Metal-ferroelectric-insulator-metal (MFIM) capacitors. Concerning (III) Performance Characteristics, the thin-film insulator can achieve Remnant polarization (Pᵣ) values up to 20 μC/cm², a coercive electric field (E_{c}) of approximately 1.5 MV/cm, and endurance exceeding 10¹¹ switching cycles without failure, with a projected non-volatile retention for over 10 years, and grain sizes of about 100 to 200 nm in diameter can be provided. Concerning (IV) applications in Advanced Electronics, the ferroelectric thin film can be included for use in electronic devices, including: Non-volatile memory (NVM) applications, such as ferroelectric random-access memory (FeRAM), ferroelectric field-effect transistors (FeFETs), ferroelectric tunnel junctions (FTJs), and multi-level cell memory; steep-slope and negative capacitance field-effect transistors (NC-FETs); Programmable logic gates; and Neuromorphic computing devices, including artificial synapses and spiking or artificial neurons. Concerning (V) use in Neuromorphic and Mott-Insulator Devices, the ferroelectric thin film can be configured as a gating insulator for three-terminal Mott-insulator-based devices for use in sensors and neuromorphic computation. Concerning (VI) doping Versatility, the method of the present disclosure may be applied to other high-k dielectrics and ferroelectrics, including but not limited to vanadium-doped hafnium zirconium oxide (V: HZO), to enhance material properties through controlled doping.

In this work the Inventors investigate for the first time the ALD deposition, processing and properties of vanadium-doped hafnium oxide (V:HfO₂) and report its unique electrical and ferroelectric material characteristics, reliability, and optimization. This new ferroelectric is compatible not only with CMOS technology but also with the gating of future VO₂ phase-change switches and sensors, utilizing a simplified all-ALD process to deposit both VO₂ and V:HfO₂ within the same ALD process and with an identical vanadium precursor.

The exemplary device vehicle for the Inventor's investigation is a metal-ferroelectric-metal (MFM) capacitor, which allows a direct comparison of the main figures of merit with those of other high-k ferroelectrics.

The process flow is depicted in FIG. 1A, where a 19 nm back electrode of titanium nitride (TiN) was deposited by RF sputtering on top of a silicon wafer with 200 nm of silicon oxide. Then a V:HfO₂ layer (16 nm) was deposited by ALD at 240° C.; tetrakis(ethylmethylamid)hafnium(IV) (TEMAH) and water (H₂O) are used as HfO₂ precursors, and tetrakis(ethylmethylamino)vanadium (TEMAV) and ozone (O₃) for VO₂.

TEMA V is one of the most common precursors for VO₂ ALD; therefore, it can be utilized to deposit both VO₂ and V:HfO₂ (as a ferroelectric gate material for 3-terminal Mott insulator devices) in a single ALD process.

To optimize the V concentration, eight sets of cycle sequences have been tested to deposit V:HfO₂ at different VO₂ cycle ratios from 3% to 11.1%. VO₂ doping cycles were distributed homogeneously between HfO₂ cycles and all the ALD processes were performed at 240° C. The structure of ALD cycles for an optimal concentration of 5.9% for VO₂ (Hf:V cycle ratio of 16:1) is illustrated in FIG. 1B.

A 19 nm TiN top electrode was then deposited by RF sputtering, and the entire stack was annealed in nitrogen (N₂) atmosphere at 600° C. for 2 minutes using a rapid thermal processing (RTP) furnace. Finally, the MFM capacitors were fabricated on diced dies by RF sputtering of 50 nm of platinum (Pt), photolithography (direct laser writing), and ion beam etching (IBE) of the unwanted Pt and top TiN.

For further investigation, similar MFM structures were fabricated under various annealing temperatures ranging from 400° C. to 800° C. for 2 minutes, and with different thicknesses of V:HfO₂ layer, ranging from 8 nm to 24 nm.

In addition, for NC tests, metal-ferroelectric-insulator-metal (MFIM) devices were made similarly, with 3 nm of Al₂O₃ as a linear dielectric deposited with ALD before the V:HfO₂ layer.

The resulting capacitive V:HfO₂ stack with optimum 5.9% V-doping level was characterized by different methods including transmission electron microscopy (TEM), energy dispersive x-ray spectroscopy (EDX), scanning electron microscopy (SEM), electron backscatter diffraction (EBSD), grazing-incidence x-ray diffraction (GIXRD) and piezoresponse force microscopy (PFM). TEM and EDX images and analysis were obtained from a lamella cross-section cut out of an electrically woken-up capacitor using focused ion beam technique. In the TEM cross-section image (FIG. 1C), a thickness of 16 nm is observed for 5.9% V:HfO₂ with 600° C. annealing, as designed with the number of ALD cycles (FIG. 1B).

FIGS. 1C and 1D are bright-field TEM images of atomic fringes in the stack, suggesting that relatively large grains of >100 nm with high crystal quality are present.

FIG. 1E depicts the SEM analysis of the surface which was conducted after the removal of the top TiN layer of a 1.5×1.5 cm² die by wet etching. In the figure, remarkably large grains, reaching sizes of about 200, are visible. In order to explore their uniformity and distribution of sizes and orientations, EBSD analysis was performed (FIG. 1F) on the same die. From this image obtained with a 30 nm step size, an equivalent circle diameter distribution has been extracted, suggesting an average grain size of about 180 nm. Note that, for the indexing of the diffraction data, the cubic phase of HfO₂ was chosen. Finally, the orientation data have been used to plot pole figures of the {100}, {110}, and {111} family of planes, showing a very weak <110> texture in the z-direction.

By comparing the results of the TEM, SEM and EBSD analysis, it was confirmed that the average grain size of the V:HfO₂ layer is approximately or about 180 nm. This relatively large grain size, unprecedented in hafnium-doped ferroelectric layers of similar thickness, structure and annealing temperature, paves the way for achieving mono-crystalline ferroelectric gated device.

Energy dispersive x-ray spectroscopy EDX was used to map the elemental distribution of the MFM stack. The extracted elemental mapping images and concentration profile, depicted in FIGS. 1G and 1H, confirm the sharp boundaries of the layers and the elemental concentration of the V:HfO₂ layer. A V-doping level of 5.6% was measured in the ferroelectric V:HfO₂ layer by EDX, which closely matches the VO₂ ratio of 5.9% in the preformed ALD process.

FIG. 1I depicts the GIXRD spectrum which was acquired at an incidence angle of 0.45° using a monochromatic Copper Kα beam from a whole 1.5×1.5 cm² die of the MFM stack.

In agreement with the literature, the most intense peak is attributed to either the (111) plane of the orthorhombic (o) phase of HfO₂, or the (101) plane of the tetragonal (t) phase. Around the main peak, the minority presence of the monoclinic (m) phase is evidenced by the peaks corresponding, from left to right, to the (−111) and (111) planes. The relatively strong signal coming from the two weak peaks on the left (from left to right, (100)ₒ and (110)ₒ, or (100)ₘ and (011)ₘ) is a good indication in favor of the ferroelectric orthorhombic phase over the paraelectric tetragonal phase. This interval was also scanned with a longer acquisition time, as reported in the inset.

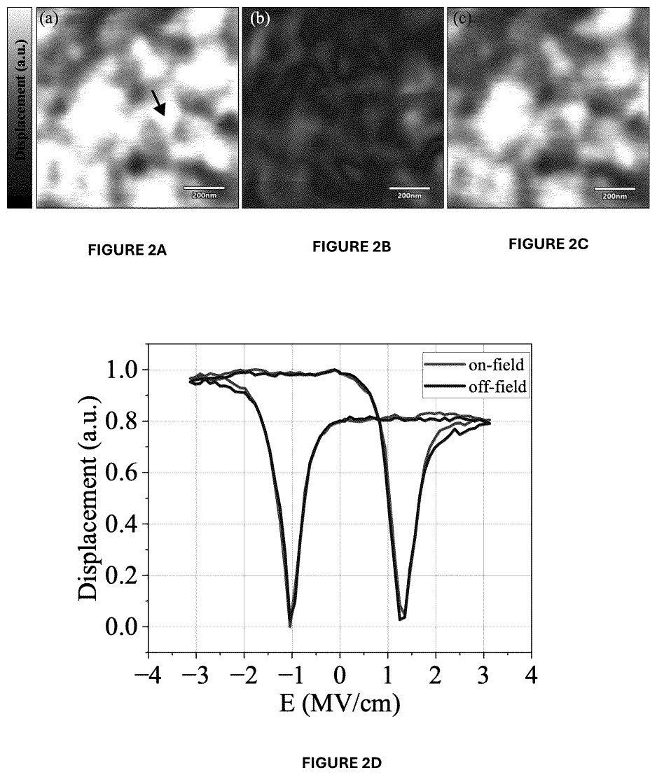

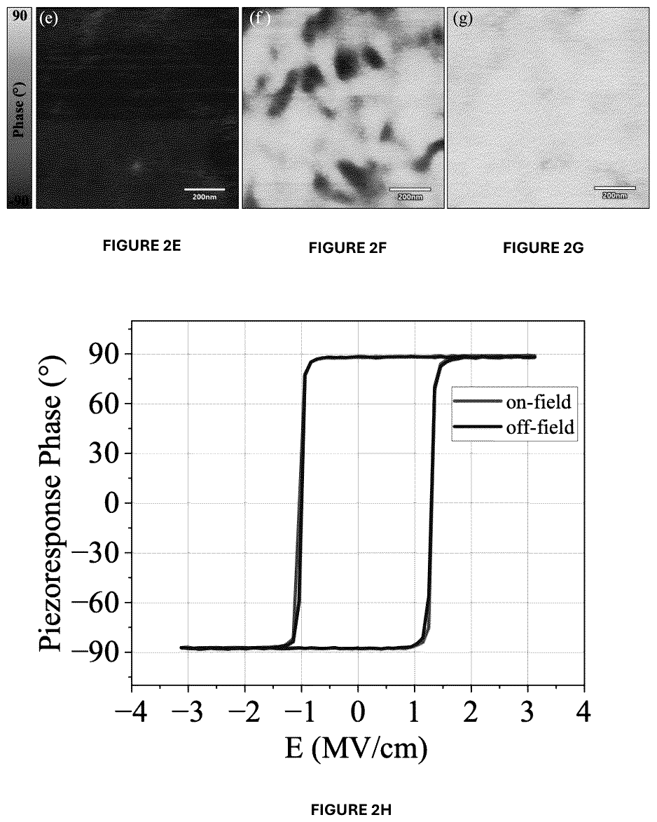

Piezoresponse force microscopy (PFM) analysis was performed on the MFM capacitors with an Asylum Research Cypher AFM instrument using conductive doped-diamond tips in nitrogen gas atmosphere. An external Zurich Instrument HF2LI lock-in amplifier was used to read out the displacement amplitude and phase value of the PFM loops and image. FIGS. 2A to 2C, 2E to 2G shows the DC off-field PFM mapping within an area of 1 μm². Switchable piezoelectric domains with lateral sizes of up to 200-300 nm are visible, which aligns with other analyses and further confirms the presence of relatively large ferroelectric grains.

FIGS. 2D and 2H represents the DC off-field and DC on-field PFM displacement and phase loops of a point marked with an arrow in FIG. 2A. The DC on- and off-field curves are well overlapped (which is a sign of good retention) and significant piezoresponse is observed.

Electrical characterization was performed on MFM capacitors with different V concentrations in their V:HfO₂ layer by polarization-voltage (P-V) and capacitance-voltage (C-V) measurements at room temperature (RT).

Before obtaining the P-V and C-V characteristics, a so-called wake-up procedure was carried out, by applying 500 initial bipolar cycles of 5V, followed by 500 bipolar cycles of 6V rectangular pulses at the same frequency.

P-V hysteresis loops were measured by applying a 10 kHz triangular voltage waveform with an amplitude of 6V and the C-V measurement was done using a 100 kHz AC 30 mV RMS signal added to a DC voltage sweep of 6V amplitude. The amplitude of ±6V (±3.75 MV/cm) was chosen to achieve the maximum saturated Pᵣ without causing ferroelectric breakdown.

The measurements were performed on a Cascade Summit 200 or SUSS MicroTec PMC150 cryogenic probe station, using a Keithley 4200 parameter analyser equipped with source-measurement unit (SMU), pulse-measurement unit (PMU) and capacitance-voltage unit (CVU). Given the size of the MFM capacitors (100×100 μm²) and the thickness of the V:HfO₂ layer, remnant polarization-electric field (Pᵣ-E), current density-electric field, and, using the ideal parallel plate capacitor approximation, relative permittivity-electric field (εᵣ-E) loops were extracted from P-V and C-V measurements for different V concentrations, as depicted in FIG. 3.

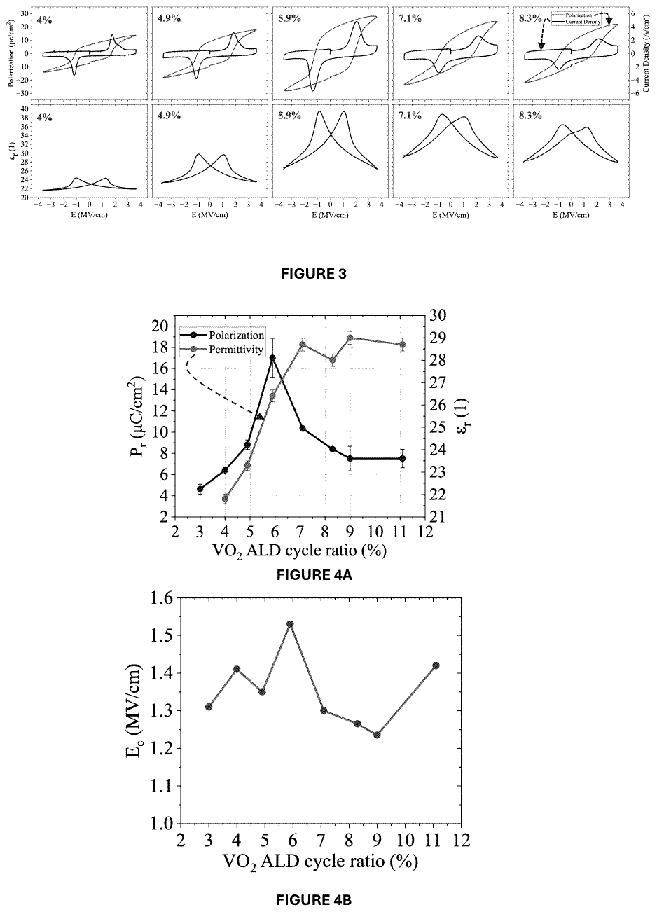

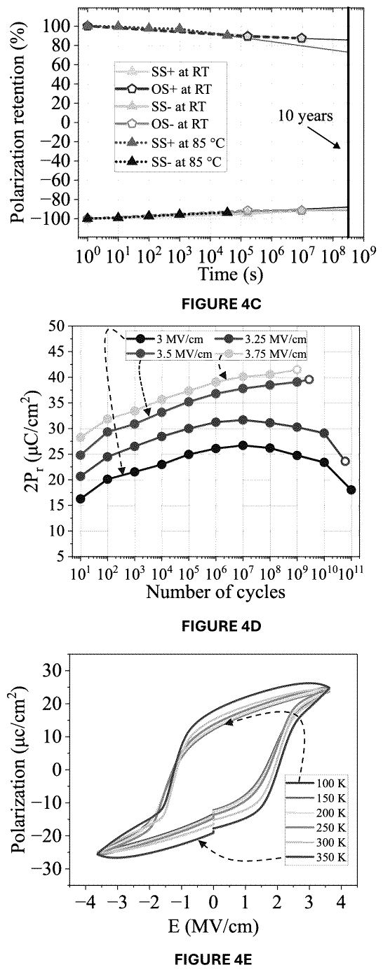

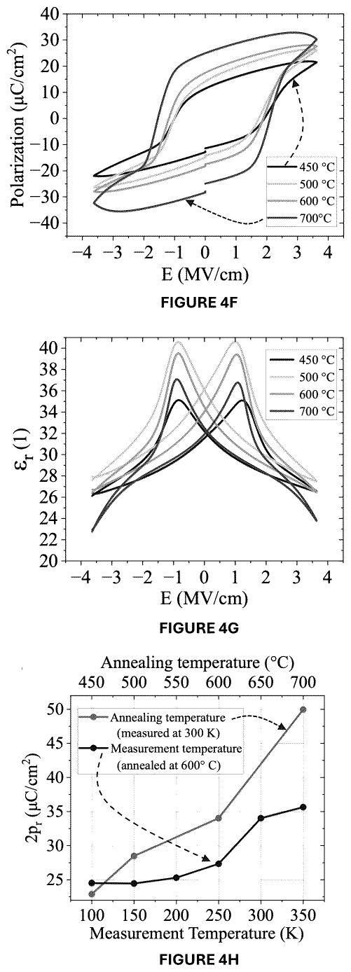

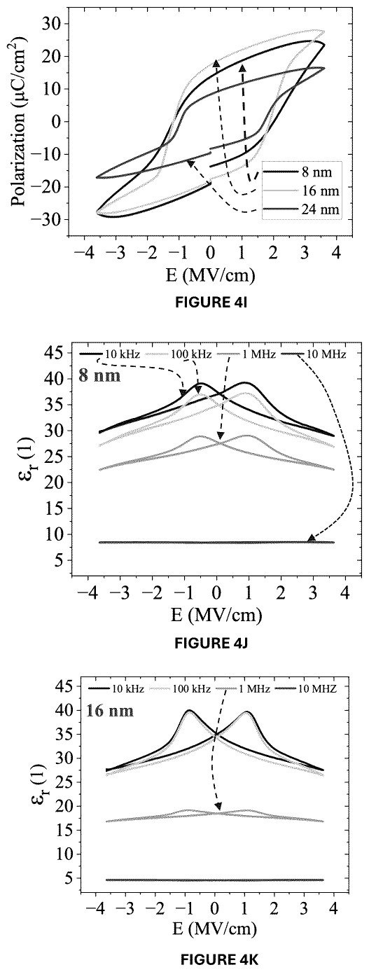

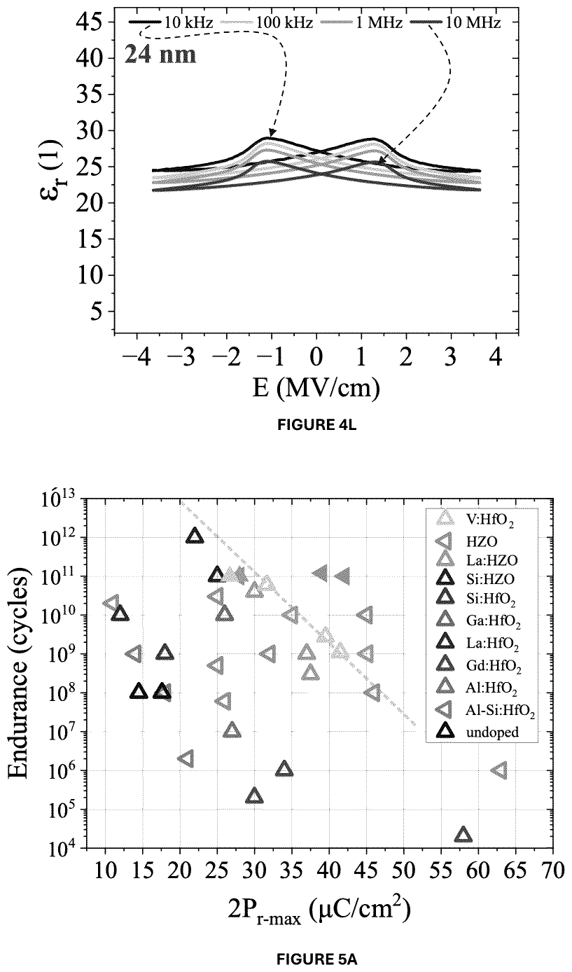

For better comparison Pᵣ and & were plotted as a function of VO₂ ALD cycle ratio for five different ratios in FIG. 4A. When different ratios are compared. Evidently, 5.9% V-doping had the largest Pᵣ and the highest quality ferroelectric response. By making five similar batches of MFM capacitors with 5.9% V-doping, an average remnant polarization of 17 μC/cm² was observed, with a maximum of 20 μC/cm².

In εᵣ-VO₂ ALD cycle ratio graph (FIG. 4A) the εᵣ values represent the minimum values of the εᵣ-E curves at maximum electric fields. It can be observed that as the V ratio increases from 3% to 5.9%, & also increases, and then approximately saturates at around 7%. A significant increase in Er occurs at 5.9% V-doping, with εᵣ of 26.4. This increasing trend is similar to what has been previously reported for hafnium zirconium oxide (HZO), where the increase in εᵣ is attributed to a reduction in the monoclinic phase fraction. However, for V:HfO₂, the increasing trend levels off after 7%, leading to saturation, which could be due to the stabilization of the minimum monoclinic phase fraction.

Coercive field (E_{c}), which is defined as E_{c}=(E_{c+}−E_{c-})/2, was also extracted from Pᵣ-E curves and plotted as a function of VO₂ ALD cycle ratio in FIG. 4B. A maximum E_{c} of 1.5 MV/cm was also observed for 5.9% V-doping.

The reliability characteristics of ferroelectric V:HfO₂ were evaluated through polarization retention and cycling endurance tests. Same-state (SS) and opposite-state (OS) retention tests were performed using similar MFM capacitors with 50 μs read/write pulses of ±5V in two sets of experiments at 85° C. and at RT. At 85° C., as shown in FIG. 4C, a retention of >90% was observed after 10 hours in both polarization directions within same-state tests following positive (SS+) and negative (SS−) pre-polarization. The capacitors were maintained at 85° C. throughout the electrical measurements and the delay time. At RT, after about 110 days, polarization retentions of >87% was observed in SS± and OS± experiments.

Long-term retention was extrapolated to 10 years, as illustrated in FIG. 4C, demonstrating the material's outstanding retention characteristics.

For the endurance test, 1 MHz pulse stimulation of 4.8V (3 MV/cm), 5.2V (3.25 MV/cm), 5.6V (3.5 MV/cm) and 6V (3.75 MV/cm) were applied to similar MFM capacitor stacks with a size of 50×50 μm². A Positive-Up-Negative-Down (PUND) method with 1 kHz triangular pulses of similar voltage amplitudes was employed to accurately measure the Pᵣ value of the ferroelectric material and exclude leakage and dielectric current contributions.

FIG. 4D shows a robust endurance of up to 10¹¹ cycles without failure with a final 2Pᵣ value of 18 μC/cm² under a pulse stimulation of 4.8V. Extended endurance tests were not feasible due to the excessively long testing time. In general, remnant polarization was increasing by cycling until about 10⁷ cycles due to wake-up effect; it then decreased due to fatigue effect. The capacitors experienced failure when stimulated with pulse amplitudes larger than 4.8 V.

To explore the temperature stability of the ferroelectric layer, P-V and C-V measurements were repeated for similar MFM capacitors at temperatures from 100 K to 350 K. As shown in FIGS. 4E and 4H, an increase in E_{c} and Pᵣ was observed at higher temperatures, which is explained by the contribution of the injected mobile charges. These tests were carried out in a SUSS MicroTec PMC150 cryogenic probe station under vacuum at a pressure of 10⁻⁵ mbar.

In order to investigate the effect of the annealing temperature, different MFM capacitors were fabricated at annealing temperatures ranging from 400° C. to 800° C., with 2-minute RTPs and similar processes. Similar electrical measurements were also performed at 300K. As depicted in FIGS. 4F and 4H, Pᵣ increased with the rise in annealing temperature and reached to a Pᵣ of 25 μC/cm₂ at 700° C. with a larger leakage current. However, permittivity increased from 450° C. to 500° C. and then decreased as the temperature was raised toward 700° C., as shown in FIG. 4G.

Pᵣ-E and εᵣ-E curves at 800° C. are not reported due to the high contribution of the leakage current and the resulting measurement problems.

Although no ferroelectricity was observed at 400° C., a remnant polarization of 11.4 μC/cm² was still obtainable at 450° C. In addition, at 425° C. a small ferroelectritiy response was observed. Annealing processes that are longer than 2 minutes at temperatures around 400° C. could be promising and warrant further investigation. These results represent the CMOS compatibility and low thermal budget of V:HfO₂ for potential applications. For a better comparison between the effect of the annealing and measurement temperatures, a summary extracted from FIGS. 4E and 4F is represented in FIG. 4H.

All previously discussed experiments were conducted on 16 nm V:HfO₂ layer. A thickness study of ferroelectric behavior was then performed by fabricating and testing similar capacitors with V:HfO₂ layer thicknesses of 8 nm, 16 nm, and 24 nm, at annealing temperature of 600° C. Electrical P-V and C-V measurements were performed at RT. As shown in FIG. 4I, the 16 nm layer exhibited the largest remnant polarization of 17 μC/cm² and the 8 nm layer had a remnant polarization of 13.8 μC/cm².

FIGS. 4J to 41 shows εᵣ-E curves obtained from C-V measurements performed on three layers at frequencies ranging from 10 kHz to 10 MHz, which was the maximum limit of the measurement system. These curves provide an informative overview to compare the frequency dispersion of ferroelectric layers in different thicknesses. Although the frequency dispersion of the 16 nm layer was larger than that of the other layers, it showed the best ferroelectric properties at 10 kHz and 100 kHz.

The ferroelectricity and Er of the 8 nm and 16 nm layers diminished as the frequency approached 10 MHz. In contrast, the 24 nm layer exhibited much smaller frequency dispersion, with an interestingly large ferroelectric response and a relatively large & at 10 MHz. This response demonstrates the potential of the 24 nm V:HfO₂ layer for high-speed memories or high-frequency applications. It also motivates further investigation on ferroelectric response of the 24 nm layer at higher frequencies using appropriate tools.

To broaden the scope of this investigation, a benchmark study was conducted to compare endurance cycles versus maximum 2Pᵣ values (observed during endurance tests) across leading reported HfO₂-based ferroelectrics in the recent scientific literature and V:HfO₂, as depicted in FIG. 5A. To provide a reliable comparison given the influence of various parameters, only studies that met the following criteria were considered: cycling frequency ≤1 MHz without recovery breaks and without pre-wake-up cycling, read frequency ≥1 kHz, final 2Pᵣ≥10 μC/cm², and homogeneous doping of ferroelectric HfO₂. Generally, as the 2Pᵣ value increases, endurance tends to decrease, a challenge commonly known as the “Pᵣ-endurance dilemma”.

Based on endurance tests at different stimulation voltages where breakdown occurred (represented by green empty symbols for V:HfO₂), a 2Pᵣ value of 25 μC/cm² was extrapolated to an endurance of 10¹² cycles. V:HfO₂ exhibits robust performance and reliability, achieving relatively large 2Pᵣ values and high endurance compared to the state of the art.

Further ferroelectricity analysis was conducted on V:HfO₂ layers through NC measurements, using a pulsed method previously proposed by Hoffmann et al., Kim et al. (see below references No. 29,30) in an MFIM stack to assess their potential for NC applications.

FIG. 5B illustrates the exemplary MFIM capacitor stack with an exemplary 3 nm Al₂O₃ layer as a linear dielectric and FIG. 5C depicts the electrical circuit schematic of the measurement.

Having the measured input pulse voltage (FIG. 5D) and resistor voltage, MFIM capacitor current, maximum stored charge (Qₘₐₓ), residual charge (Qᵣₑₛ) and the difference of them (Q_{d}) was extracted as shown in FIGS. 5E and 5G. Then the P-E_{f} curve was calculated and plotted, as shown in FIG. 5H. A visible ‘S’-shaped curve was observed, consistent with the Landau-Ginzburg-Devonshire (LGD) theory.

Finally, an equivalent capacitance value of about −600 pF was extracted for the ferroelectric using the slope value of curve (dashed line in FIG. 5H), which clearly demonstrates the promising potential of V:HfO₂ layer for NC applications similar to previous findings for Si:HfO₂ and HZO.

The Inventors thus demonstrate a CMOS-compatible ferroelectric that is V-doped HfO₂, by fabricating and characterizing several V:HfO₂ thin films, identifying a preferred 5.9% doping level, in terms of ferroelectric performance.

The versatility of this new ferroelectric extends to compatibility with future VO₂ Mott insulator devices, by a simplified all-ALD process with, for example, an identical vanadium precursor.

The Inventors established that the novel doping with V enables obtaining Pᵣ of about 20 μC/cm², E_{c} of 1.5 MV/cm, excellent endurance of >10¹¹ cycles without failure and 10-year non-volatile (NV) retention, competing with leading materials in the field.

Material characterization suggests the presence of much larger grain sizes, with respect to other HfO₂-based ferroelectrics, corroborating the strong piezoresponse detected by PFM.

The robust polarization switching, endurance characteristics and retention properties of the thin film make it an ideal and reliable candidate for non-volatile memory and neuromorphic devices. Finally, its potential for NC devices is supported by pulsed negative capacitance measurements.

The word “about” as used herein means the identified value plus/minus 5%. “On” as used herein covers both directly on, and indirectly on with intervening element(s) therebetween. Thus, for example, if element A is stated to be “on” element B, this covers element A being directly and/or indirectly on element B. Likewise, “supported by” as used herein covers both in physical contact with, and indirectly supported by with intervening element(s) therebetween.

Each embodiment herein may be used in combination with any other embodiment(s) described herein.

While the disclosure has been illustrated and described with reference to various example embodiments, it will be understood that the various embodiments are intended to be illustrative, not limiting. It will further be understood by those skilled in the art that various changes in form and detail may be made without departing from the true spirit and full scope of the disclosure, including the appended claims and their equivalents. It will also be understood that any of the embodiment(s) described herein may be used in combination with any other embodiment(s) described herein.

### REFERENCES

(1) Böscke, T. S.; Müller, J.; Bräuhaus, D.; Schröder, U.; Böttger, U. Ferroelectricity in hafnium oxide thin films. Applied Physics Letters 2011, 99, 102903.
(2) Müller, F.; De, S.; Olivo, R.; Lederer, M.; Altawil, A.; Hoffmann, R.; Kämpfe, T.; Ali, T.; Dünkel, S.; Mulaosmanovic, H.; Müller, J.; Beyer, S.; Seidel, K.; Gerlach, G. Multilevel Operation of Ferroelectric FET Memory Arrays Considering Current Percolation Paths Impacting Switching Behavior. IEEE Electron Device Letters 2023, 44, 757-760.
(3) Salahuddin, S.; Datta, S. Use of Negative Capacitance to Provide Voltage Amplification for Low Power Nanoscale Devices. Nano Letters 2008, 8, 405-410, Publisher: American Chemical Society.
(4) Kamaei, S.; Liu, X.; Saeidi, A.; Wei, Y.; Gastaldi, C.; Brugger, J.; Ionescu, A. M. Ferroelectric gating of two-dimensional semiconductors for the integration of steep-slope logic and neuromorphic devices. Nature Electronics 2023, 6, 658-668.
(5) Park, M. H.; Lee, Y. H.; Kim, H. J.; Kim, Y. J.; Moon, T.; Kim, K. D.; Müller, J.; Kersch, A.; Schroeder, U.; Mikolajick, T.; Hwang, C. S. Ferroelectricity and Antiferro-electricity of Doped Thin HfO₂-Based Films. Advanced Materials 2015, 27, 1811-1831.
(6) Hsain, H. A.; Lee, Y.; Materano, M.; Mittmann, T.; Payne, A.; Mikolajick, T.; Schroeder, U.; Parsons, G. N.; Jones, J. L. Many routes to ferroelectric HfO₂: A review of current deposition methods. Journal of Vacuum Science & Technology A 2022, 40, 010803.
(7) Müller, J.; Böscke, T. S.; Schröder, U.; Mueller, S.; Bräuhaus, D.; Böttger, U.; Frey, L.; Mikolajick, T. Ferroelectricity in Simple Binary ZrO₂ and HfO₂. Nano Letters 2012, 12, 4318-4323.
(8) Kozodaev, M. G.; Chernikova, A. G.; Korostylev, E. V.; Park, M. H.; Schroeder, U.; Hwang, C. S.; Markeev, A. M. Ferroelectric properties of lightly doped La:HfO₂ thin films grown by plasma-assisted atomic layer deposition. Applied Physics Letters 2017, 111, 132903.
(9) Huang, T.; Li, Y.-C.; Chen, C.-F.; Li, X.-X.; Gu, Z.-Y.; Zhang, D. W.; Zhu, X.-N.; Lu, H.-L. Demonstration of Robust Breakdown Reliability and Enhanced Endurance in Gallium Doped HfO₂ Ferroelectric Thin Films. IEEE Electron Device Letters 2023, 44, 1476-1479, Conference Name: IEEE Electron Device Letters.
(10) Florent, K.; Lavizzari, S.; Popovici, M.; Di Piazza, L.; Celano, U.; Groeseneken, G.; Van Houdt, J. Understanding ferroelectric Al:HfO₂ thin films with Si-based electrodes for 3D applications. Journal of Applied Physics 2017, 121, 204103.
(11) Yun, Y.; Buragohain, P.; Li, M.; Ahmadi, Z.; Zhang, Y.; Li, X.; Wang, H.; Li, J.; Lu, P.; Tao, L.; Wang, H.; Shield, J. E.; Tsymbal, E. Y.; Gruverman, A.; Xu, X. Intrinsic ferroelectricity in Y-doped HfO₂ thin films. Nature Materials 2022, 21, 903-909, Publisher: Nature Publishing Group.
(12) Prasadam, V. P.; Bahlawane, N.; Mattelaer, F.; Rampelberg, G.; Detavernier, C.; Fang, L.; Jiang, Y.; Martens, K.; Parkin, I. P.; Papakonstantinou, I. Atomic layer deposition of vanadium oxides: process and application review. Materials Today Chemistry 2019, 12, 396-423.
(13) Park, M. H.; Lee, Y. H.; Mikolajick, T.; Schroeder, U.; Hwang, C. S. Review and perspective on ferroelectric HfO₂-based thin films for memory applications. MRS Com-munications 2018, 8, 795-808.
(14) Wang, Y. et al. A stable rhombohedral phase in ferroelectric Hf(Zr)1+x O2 capacitor with ultralow coercive field. Science 2023, 381, 558-563.
(15) Wang, Y.; Yang, Y.; Jiang, P.; Lv, S.; Wang, B.; Chen, Y.; Ding, Y.; Gong, T.; Luo, Q. Precrystallization Engineering of Hf0.5Zr0.5O2 Film in Back-End-of-Line Compatible Ferroelectric Device for Enhanced Remnant Polarization and Endurance. IEEE Electron Device Letters 2023, 44, 396-399, Conference Name: IEEE Electron Device Letters.
(16) Lomenzo, P. D.; Li, S.; Pintilie, L.; Istrate, C. M.; Mikolajick, T.; Schroeder, U. Memory Window Enhancement in Antiferroelectric RAM by Hf Doping in ZrO₂. IEEE Electron Device Letters 2022, 43, 1447-1450, Conference Name: IEEE Electron Device Letters.
(17) Senapati, A.; Lou, Z.-F.; Lee, J.-Y.; Chen, Y.-P.; Huang, S.-Y.; Maikap, S.; Lee, M.-H.; Liu, C.-W. Low Polarization Loss of Long Endurance on Scavenged Ru-Based Electrode Ferroelectric Hf0.5Zr0.5O2 by Optimizing TiNx Interfacial Capping Layer and Its Fatigue Mechanism. IEEE Electron Device Letters 2024, 45, 673-676, Conference Name: IEEE Electron Device Letters.
(18) Cao, R.; Song, B.; Shang, D.; Yang, Y.; Luo, Q.; Wu, S.; Li, Y.; Wang, Y.; Lv, H.; Liu, Q.; Liu, M. Improvement of Endurance in HZO-Based Ferroelectric Capacitor Using Ru Electrode. IEEE Electron Device Letters 2019, 40, 1744-1747, Conference Name: IEEE Electron Device Letters.
(19) Toprasertpong, K.; Tahara, K.; Hikosaka, Y.; Nakamura, K.; Saito, H.; Takenaka, M.; Takagi, S. Low Operating Voltage, Improved Breakdown Tolerance, and High Endurance in Hf0.5Zr0.5O2 Ferroelectric Capacitors Achieved by Thickness Scaling Down to 4 nm for Embedded Ferroelectric Memory. ACS Applied Materials & Interfaces 2022, 14, 51137-51148, Publisher: American Chemical Society.
(20) Lyu, J.; Song, T.; Fina, I.; Sánchez, F. High polarization, endurance and retention in sub-5 nm Hf0.5 Zr0.5O2 films. Nanoscale 2020, 12, 11280-11287.
(21) Lyu, J.; Fina, I.; Bachelet, R.; Saint-Girons, G.; Estandía, S.; Gázquez, J.; Fontcuberta, J.; Sánchez, F. Enhanced ferroelectricity in epitaxial Hf0.5Zr0.5O2 thin films integrated with Si(001) using SrTiO3 templates. Applied Physics Letters 2019, 114, 222901.
(22) Chernikova, A. G.; Kozodaev, M. G.; Negrov, D. V.; Korostylev, E. V.; Park, M. H.; Schroeder, U.; Hwang, C. S.; Markeev, A. M. Improved Ferroelectric Switching Endurance of La-Doped Hf0.5Zr0.5O2 Thin Films. ACS Applied Materials & Interfaces 2018, 10, 2701-2708, Publisher: American Chemical Society.
(23) Kozodaev, M.; Chernikova, A.; Korostylev, E.; Park, M.; Khakimov, R.; Hwang, C.; Markeev, A. Mitigating wakeup effect and improving endurance of ferroelectric HfO 2-ZrO 2 thin films by careful La-doping. Journal of Applied Physics 2019, 125.
(24) Tai, L.; Wei, W.; Sang, P.; Li, X.; Dou, X.; Zhao, G.; Jiang, P.; Luo, Q.; Zhan, X.; Wu, J.; Chen, J. Silicon Atomic-Layer Doped Hf0.7Zr0.3O2 Films: Toward Low Coercive Field (0.64 MV/cm) and High Endurance (>10¹² Cycles). IEEE Transactions on Electron Devices 2024, 71, 4403-4406, Conference Name: IEEE Transactions on Electron Devices.
(25) Grenouillet, L. et al. Nanosecond Laser Anneal (NLA) for Si-Implanted HfO₂ Ferro-electric Memories Integrated in Back-End of Line (BEOL). 2020 IEEE Symposium on VLSI Technology. 2020; pp 1-2, ISSN: 2158-9682.
(26) Hoffmann, M.; Schroeder, U.; Schenk, T.; Shimizu, T.; Funakubo, H.; Sakata, O.; Pohl, D.; Drescher, M.; Adelmann, C.; Materlik, R.; Kersch, A.; Mikolajick, T. Stabilizing the ferroelectric phase in doped hafnium oxide. Journal of Applied Physics 2015, 118, 072006.
(27) Lomenzo, P. D.; Takmeel, Q.; Zhou, C.; Chung, C.-C.; Moghaddam, S.; Jones, J. L.; Nishida, T. Mixed Al and Si doping in ferroelectric HfO₂ thin films. Applied Physics Letters 2015, 107, 242903.
(28) D. Kim, K.; H. Park, M.; J. Kim, H.; J. Kim, Y.; Moon, T.; H. Lee, Y.; D. Hyun, S.; Gwon, T.; S. Hwang, C. Ferroelectricity in undoped-HfO 2 thin films induced by deposition temperature control during atomic layer deposition. Journal of Materials Chemistry C 2016, 4, 6864-6872, Publisher: Royal Society of Chemistry.
(29) Hoffmann, M.; Fengler, F. P. G.; Herzig, M.; Mittmann, T.; Max, B.; Schroeder, U.; Negrea, R.; Lucian, P.; Slesazeck, S.; Mikolajick, T. Unveiling the double-well energy landscape in a ferroelectric layer. Nature 2019, 565, 464-467.
(30) Kim, Y. J.; Yamada, H.; Moon, T.; Kwon, Y. J.; An, C. H.; Kim, H. J.; Kim, K. D.; Lee, Y. H.; Hyun, S. D.; Park, M. H.; Hwang, C. S. Time-Dependent Negative Capacitance Effects in Al2O3/BaTiO3 Bilayers. Nano Letters 2016, 16, 4375-4381, Publisher: American Chemical Society.
(31) Landau, L. The Theory of Phase Transitions. Nature 1936, 138, 840-841, Publisher: Nature Publishing Group.
(32) Ginzburg, V. On the dielectric properties of ferroelectric (seignetteelectric) crystals and barium titanate. Zh. eksp. teor. Fiz 1945, 15, 739.
(33) Devonshire, A. F. XCVI. Theory of barium titanate. The London, Edinburgh, and Dublin Philosophical Magazine and Journal of Science 1949, Publisher: Taylor & Francis Group.
(34) Gastaldi, C.; Saeidi, A.; Cavalieri, M.; Stolichnov, I.; Muralt, P.; Ionescu, A. M. Transient Negative Capacitance of Silicon-doped HfO₂ in MFMIS and MFIS structures: experimental insights for hysteresis-free steep slope NC FETs. 2019 IEEE International Electron Devices Meeting (IEDM). 2019; pp 23.5.1-23.5.4, ISSN: 2156-017X.

1. A ferroelectric device comprising at least one support and at least one ferroelectric layer provided on the at least one support, wherein the at least one ferroelectric layer comprises vanadium-doped Hafnium Oxide.

2. The ferroelectric device according to claim 1, wherein the vanadium-doping concentration is between 3 at. % and 11 at. %.

3. The ferroelectric device according to claim 1, wherein the vanadium-doped Hafnium Oxide layer has a grain size >10 nm; and <1000 nm.

4. The ferroelectric device according to claim 1, wherein the vanadium-doped Hafnium Oxide layer has a thickness between 1 nm and 25 nm.

5. The ferroelectric device according to claim 1, wherein the vanadium-doped Hafnium Oxide ferroelectric layer is a CMOS-compatible ferroelectric thin-film insulator.

6. The ferroelectric device according to claim 1, including at least one electrode, wherein the at least one ferroelectric layer comprising vanadium-doped Hafnium Oxide is provided in electrical contact and operatively connected with the at least one electrode for applying an electrical potential difference to the at least one ferroelectric layer.

7. The ferroelectric device according to claim 6, including at least first and second electrodes, and the at least one ferroelectric layer comprising vanadium-doped Hafnium Oxide is provided in electrical contact and operatively connected with the first and second electrodes for applying an electrical potential difference to the at least one ferroelectric layer.

8. The ferroelectric device according to claim 7, wherein the ferroelectric device forms a ferroelectric capacitor device.

9. The ferroelectric device according to claim 8, wherein the ferroelectric device forms a metal-ferroelectric-metal device.

10. The ferroelectric device according to claim 8, wherein the ferroelectric device forms a metal-ferroelectric-insulator-metal device including at least one insulator material located between the first or second electrode and the at least one ferroelectric layer.

11. The ferroelectric device according to claim 6, wherein the ferroelectric device forms a metal-ferroelectric-semiconductor device including at least one semiconductor material or layer, wherein the at least one ferroelectric layer comprising vanadium-doped Hafnium Oxide is provided in electrical contact and operatively connected with the at least one electrode and the at least one semiconductor material or layer.

12. An electronic device including the ferroelectric device according to claim 6, and including at least one device gate, the at least one device gate including the ferroelectric device, wherein the electronic device is at least one of a VO₂ phase-change switch, a VO₂ phase-change sensor, a ferroelectric field-effect transistor, a negative capacitor, and a negative capacitance field-effect transistor.

13. An electronic device including the ferroelectric device according to claim 6, wherein the electronic device is at least one of: a non-volatile memory, a ferroelectric random-access memory, a multi-level cell memory, and a negative capacitance capacitor.

14. An electronic device including the ferroelectric device according to claim 6, wherein the electronic device is at least one of: a ferroelectric tunnel junction, a programmable logic gate, a neuromorphic computing device, an artificial synapse, and an artificial neuron.

15. Electronic device including the ferroelectric device according to claim 6, wherein the electronic device comprises at least one three-terminal Mott-Insulator device, wherein the at least one ferroelectric layer is configured as a gating insulator for the three-terminal Mott-insulator device.

16. A Ferroelectric device fabrication method, comprising:
providing at least one support; and
depositing vanadium-doped Hafnium Oxide layer by atomic layer deposition on the at least one support,
wherein the vanadium-doped Hafnium Oxide layer is deposited by atomic layer deposition using tetrakis(ethylmethylamid)hafnium(IV) and water as HfO₂ precursors, and
wherein tetrakis(ethylmethylamino)vanadium and at least one of: ozone and oxygen are used as VO₂ precursors.

17. The method according to claim 16, wherein VO₂ doping cycles are distributed between HfO₂ cycles during deposition of the vanadium-doped Hafnium Oxide layer.

18. The method according to claim 17, wherein a Hf:V cycle ratio is used to provide a vanadium-doping concentration level that is between 3 at. % and 11 at. %

19. The method according to claim 16, wherein the deposited vanadium-doped Hafnium Oxide layer has a thickness between 1 nm and 25 nm.

20. The method according to claim 16, including depositing at least one electrode on the at least one support for electrically contacting and operatively connecting with the vanadium-doped Hafnium Oxide layer and for applying an electrical potential difference to the vanadium-doped Hafnium Oxide layer.
